(19) United States
(12) Patent Application Publication
(10) Pub. No.: US 2010/0123084 A1
(43) Pub. Date: May 20, 2010

(54) Betavoltaic radiation detector

(75) Inventors: Elise B. Fox, Aiken, SC (US); Kevin M. Fox, Aiken, SC (US)

Correspondence Address: J. BENNETT MULLINAX, LLC, P. O. BOX 26029, GREENVILLE, SC, 29616-1029, US

(73) Assignee: Savannah River Nuclear Solutions, LLC, Aiken, SC (US)

(21) Appl. No.: 12/592,016

(22) Filed: Nov. 18, 2009

Related U.S. Application Data
(60) Provisional application No. 61/199,465, filed on Nov. 18, 2008.

(51) Int. Cl. G01T 1/24; H01L 29/24

(52) U.S. Cl. 250/370.14; 257/77; 257/E29.104

(57) ABSTRACT

A detector for beta particles emitted from a radioisotope is provided by applying a reverse bias to a betavoltaic cell having a 4H silicon carbide semiconductor and using an outer exposure surface of the p-type layer of the semiconductor as the surface for receiving radiation.

### RELATED APPLICATIONS

This application claims the benefit of U.S. application Ser. No. 61/199,465 filed on Nov. 18, 2008 and which is incorporated herein by reference.

### STATEMENT AS TO RIGHTS TO INVENTIONS MADE UNDER FEDERALLY SPONSORED RESEARCH AND DEVELOPMENT

This invention was made with Government support under Contract No. DE-AC09-96SR18500 awarded by the United States Department of Energy. The Government has certain rights in the invention.

### FIELD OF THE INVENTION

This invention relates to radiation detectors and, more particularly, to the detection of single event emission of beta particles.

### BACKGROUND OF THE INVENTION

Beta particles are high energy, high speed electrons or positrons emitted by certain types of radioactive nuclei such as potassium-40. Beta particles as emitted are a form of ionizing radiation sometimes called beta rays. The production of beta particles is termed beta decay. An isotope with an unstable atomic nucleus with an excess of neutrons may undergo beta decay when a neutron is converted into a proton, an electron and an electron-type neutrino. Beta particles are emitted by such isotopes as strontium-90 and find uses in measuring devices and treatment of certain types of cancer. The detection of the presence of a beta emitter is also of great importance.

Betavoltaic cells are semiconductor devices that operate similarly to photovoltaics. When a beta particle (or a photon in the case of a photovoltaic) strikes the p-n junction in a semiconductor, an electron/hole pair is created which results in the generation of a small current across the junction.

Betavoltaic cells are generators of electrical current somewhat like a battery but which are designed to use energy from a radioactive source in the form of emitted beta particles although the cell may also be sensitive to photons. The function of a betavoltaic device is similar to that of a solar panel which converts photons into an electric current. However, while the betavoltaic cell does include a semiconductor like a photovoltaic cell, it must also include a radioactive material that emits electrons. When emitted electrons (beta particles) strike at the interface that forms the two layers of a junction between the semiconductor, that is, the p-n junction, a current may be generated as the semiconductor acts as a rectifier allowing current to flow in only one direction.

In the past, semiconductors have been used for radiation detection and one such device is disclosed in U.S. Pat. No. 3,265,899 to J. W. Bergstrom, et al. where a radiation detector that is referred to as a reverse bias diode is described. In this patent, a semiconductor body has a p-type conductivity area and an n-type conductivity area that form a junction so that when current flows through the semiconductor body it is in one direction. By applying a voltage difference between the p and n areas with a battery to cause current to flow, a magnetic field is created around the junction. This field is sensitive to incident radiation in the junction area and the radiation that strikes the field will cause it to vary and create a detectible change in the current. However, the sensitive area is in the area immediately adjacent to the p-n junction whereas it is an object of the present invention to detect particles that penetrate the junction.

In U.S. Pat. No. 3,621,257 which issued to Phillip A. Johnston, et al. on Nov. 16, 1971, a beta particle detection method is described wherein a thin detector is employed which includes a means for scattering particles back into the detector. However, it is an object of the present invention to measure single events so that back scattering is not a feasible or desirable feature.

Traditional betavoltaic cells frequently employ a silicon-based, solid state radiation detector. However, such detectors have a higher leakage current which reduces the detection limits of the device.

Accordingly, there remains room for improvement in variation in the art.

### SUMMARY OF THE INVENTION

It is one aspect of at least one of the present embodiments to provide a method of detecting single beta particle emissions from a radioisotope by exposing a surface of a semiconductor in a betavoltaic cell directly to the radioisotope.

It is another aspect of at least one of the present embodiments to provide method for detecting single event emissions of beta particles from a radioisotope comprising the steps of providing a silicon carbide, forward biased betavoltaic cell having a p-type and a n-type layer with a junction therebetween; preferably applying a reverse bias to the cell to provide gain through avalanche breakdown; or, alternatively, for selected isotope detection, applying no bias, exposing a surface of a p-type layer to a radioisotope source of beta particle radiation; and measuring the change in the current from one of the layers to the other whereby changes in the current indicate the penetration of a beta particle into the surface.

It is a further aspect of at least one embodiment of the present invention to provide for a detector for a single incident emission of a beta particle from a radioisotope comprising a silicon carbide, p-n junction semiconductor having an exterior surface of its p-type layer exposed for directly receiving a beta particle emitted from a radioisotope, the thickness of the semiconductor being at least the penetration depth of a tritium beta particle; means for applying a reverse bias of a selected level to the semiconductor whereby a single beta particle penetrating the surface of the p-type layer will cause a cascade of electrons across the junction; and means for measuring the current change produced by the cascade thereby detecting the presence of a beta particle. Preferably the semiconductor comprises 4H silicon carbide and the reverse bias voltage will be in the range of approximately 100 to 1000 volts.

It is a further aspect of at least one embodiment of the present invention to provide for a betavoltaic detector and method of detecting which has sufficiently high sensitivity so as to be useful for detecting tritium. Current techniques for tritium monitoring tend to be labor intensive (smears), time consuming or destructive to samples (liquid scintillation), or require much larger instruments having greater maintenance needs such as ion chambers.

### BRIEF DESCRIPTION OF THE DRAWINGS

A fully enabling disclosure of the present invention, including the best mode thereof to one of ordinary skill in the art, is set forth more particularly in the remainder of the specification, including reference to the accompanying drawings.

FIG. 1 is a schematic representation of one embodiment of the present invention.

### DESCRIPTION OF THE PREFERRED EMBODIMENT

Reference will now be made in detail to the embodiments of the invention, one or more examples of which are set forth below. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used on another embodiment to yield a still further embodiment. Thus, it is intended that the present invention cover such modifications and variations as come within the scope of the appended claims and their equivalents. Other objects, features, and aspects of the present invention are disclosed in the following detailed description. It is to be understood by one of ordinary skill in the art that the present discussion is a description of exemplary embodiments only and is not intended as limiting the broader aspects of the present invention, which broader aspects are embodied in the exemplary construction.

In describing the various figures herein, the same reference numbers are used throughout to describe the same material, apparatus, or process pathway. To avoid redundancy, detailed descriptions of much of the apparatus once described in relation to a figure is not repeated in the descriptions of subsequent figures, although such apparatus or process is labeled with the same reference numbers.

This invention is a sensor for detecting the presence and concentration of radioisotopes that emit beta radiation by using a betavoltaic cell in a novel manner. Betavoltaic cells are similar in operation to photovoltaic cells except that the band gap and junction depth of the device are tailored for the capture of beta particles rather than photons. It has been discovered that the 4H polytype of silicon carbide is an ideal material for use as the cell substrate due to its excellent resistance to radiation damage and its very low leakage current.

To be used as a detector according to the present invention, a reverse bias is applied to the betavoltaic cell so that it acts as a high resistance diode. Electrons or holes are excited from the valance band into the conduction band by incident beta particles. Under the strong reverse bias, the electrons or holes are accelerated towards the depleted region of the p-n junction, ionizing lattice atoms and producing secondary electron-hole pairs. These, in turn, are also accelerated producing a cascading effect that results in the generation of hundreds to thousands of electron-hole pairs for a single incident beta particle. Detection of a single beta emission event is, therefore, achieved. An electrometer is used to monitor the current flowing through the betavoltaic cell. Changes in the current are then correlated with the concentration of the radioisotope present using a calibration curve.

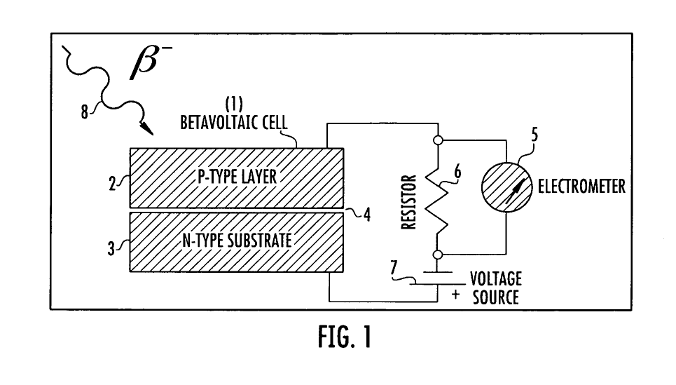

Turning now to FIG. 1, a schematic representation based on operation of the sensor including the reverse bias betavoltaic cell is shown. Betavoltaic cell 1 is shown with p-type layer 2 and n-type layer 3 joined at junction 4 which is a p-n junction. To provide the reverse bias, a battery or voltage source 7 is illustrated having its positive terminal in communication with the n-type substrate and its negative terminal in communication with the p-type layer through resistor 6. Electrometer 5 is connected across resistor 6. In the present invention, when a beta particle 8 strikes the surface of the p-type layer it will cause a measurable change in the current flow through the resistor 6 so that the change will be detected by electrometer 5.

The 4H silicon carbide semiconductor material represents the best mode of the invention. However, within the scope of this invention other semiconductor materials may be used. In addition, the thickness of the p-layer is preferably that of the penetration depth of the beta particles of interest for detection.

In one embodiment of the invention, the sensor illustrated schematically in FIG. 1 may be housed within a light-tight metal enclosure which provides shielding from electromagnetic interference. Evaluations of various beta emitters such as Sr-90 and Pu-239 radiation sources were made at various distances from the face of the sensor. It was determined that the detector output varied proportionally with both the activity of the source and the distance between the source and the sensor as measured by a high sensitivity electrometer used to measure sensor output.

By way of example, a 4.5u curie Sr-90 radiation source was placed two inches from the face of the betavoltaic detector. The source was placed perpendicular to the detector, therefore reducing the output of the radiation source because of a less than favorable orientation. However, following the incorporation of an attached electrometer, the detector measured an output of 0.064 picoamperes. A control test made without a radiation source had a measured output of less than 0.001 picoamperes. Measurements were made without applying a reverse bias to the sensor.

Using an array of multiple betavoltaic cells, a sensor could be configured to provide for even stronger output current. In addition, it is believed that applying a reverse-bias to the sensor would also provide significant improvement in output current.

Although preferred embodiments of the invention have been described using specific terms, devices, and methods, such description is for illustrative purposes only. The words used are words of description rather than of limitation. It is to be understood that changes and variations may be made by those of ordinary skill in the art without departing from the spirit or the scope of the present invention which is set forth in the following claims. In addition, it should be understood that aspects of the various embodiments may be interchanged, either in whole, or in part. Therefore, the spirit and scope of the appended claims should not be limited to the description of the preferred versions contained therein.

We claim:

1. A detector for single incident emission of a beta particle from a radioisotope comprising:
a) a silicon carbide, p-n junction semiconductor having the surface of its p-type layer exposed for directly receiving a beta particle emitted from a radioisotope; the depth of said junction being selected to conform to an average penetration depth of beta particles from the isotope of interest for detection;
b) means for applying a reverse bias to said semiconductor whereby a single beta particle generating an electron-hole pair at the p-n junction will cause a cascade of electron-hole pairs; and
c) means for measuring the change in current produced by said cascade thereby detecting the penetration of a beta particle.

2. The detector of claim 1 whereby the semiconductor comprises 4H silicon carbide.

3. The detector of claim 1 wherein reverse bias means applied voltage in the range of about 100 to 1000 volts.

4. A method of detecting single event beta emission from a radioisotope comprising the steps of:
a) providing a betavoltaic cell having a p-n junction semiconductor;
b) applying a reverse bias to said semiconductor;
c) exposing a surface of such semiconductor directly to a beta emitting radioisotope; and
d) measuring the current fluctuation across said semiconductor to indicate the emission of a beta particle.

5. A method for detecting single event emission of a beta particle from a radioisotope comprising the steps of:
a) providing a silicon carbide, forward biased, betavoltaic cell having a p-type and a n-type layer with a junction therebetween;
b) applying a reverse bias to said cell greater than the forward bias of said cell;
c) exposing a surface of the p-type layer to a radioisotope source of a beta particle; and
d) measuring the change in current across the cell which indicates the penetration of a beta particle into said surface.
